(19) United States
(12) Patent Application Publication
(10) Pub. No.: US 2012/0260962 A1
(43) Pub. Date: Oct. 18, 2012

(54) ELECTRICAL GENERATOR USING THE THERMOELECTRIC EFFECT AND TWO CHEMICAL REACTIONS, I.E. EXOTHERMIC AND ENDOTHERMIC REACTIONS, TO GENERATE AND DISSIPATE HEAT, RESPECTIVELY

(75) Inventors: Tristan Caroff, Brest (FR); Philippe Coronel, Barraux (FR); Jean-Antoine Gruss, Seyssinet-Pariset (FR); Marc Plissonnier, Eybens (FR)

(73) Assignee: COMMISSARIAT A L'ENERGIE ATOMIQUE ET AUX ENERGIES ALTERNATIVES, Paris (FR)

(21) Appl. No.: 13/510,746

(22) PCT Filed: Nov. 16, 2010
(86) PCT No.: PCT/FR10/00769

§ 371 Date: Jun. 21, 2012

(30) Foreign Application Priority Data
Nov. 18, 2009 (FR) 09 05537

(51) Int. Cl. H01L 35/30; H01L 35/34

(52) U.S. Cl. 136/205; 136/201

(57) ABSTRACT

An electric generator based on a thermoelectric effect includes at least a heat source, a heat dissipator and a thermoelectric converter provided with at least two areas respectively in contact with the heat source and the heat dissipator. The heat source is the center of an exothermic chemical reaction, such as the catalytic combustion of hydrogen. The heat dissipator is the center of an endothermic chemical reaction, at least one product of which forms one of the reagents of the exothermic chemical reaction. Once it is formed by the heat dissipator, said product is then directed towards the input of the heat source in order to react there. The endothermic chemical reaction is more particularly a steam reforming reaction for methanol.

### TECHNICAL FIELD OF THE INVENTION

The invention relates to an electric generator based on a thermoelectric effect including at least:
a heat source, center of an exothermic chemical reaction and including means for supplying with least one reagent said exothermic chemical reaction,
a heat dissipator, center of an endothermic chemical reaction and including means for evacuating at least one product of the endothermic chemical reaction,
and a thermoelectric converter provided with at least two areas respectively in contact with the heat source and the heat dissipator.

The invention also relates to a method for implementing such an electric generator based on a thermoelectric effect.

The invention also relates to a method for manufacturing such a generator.

### STATE OF THE ART

Currently, large efforts are made for developing transportable electric generators.

One of the possible ways to produce a transportable electric generator consists in using a thermoelectric converter, i.e. an operative device based on the principle of the conversion of a thermal energy into electric energy, by Seebeck effect.

In particular, as represented in FIG. 1, such a converter 1 contains a module formed by a series of several couples connected electrically in series and thermically in parallel.

Each couple is in particular constituted of a thermoelement 2a, formed by a conducting or semiconducting material having a positive Seebeck coefficient, and constituted of a thermoelement 2b, formed by a conducting or semiconducting material having a negative Seebeck coefficient. The thermoelements 2a and 2b are connected to each other in twos by junctions 3a (hot-side junctions) or 3b (cold-side junctions), formed by an electrically conducting material, in order to obtain an electric connection in series of said thermoelements. Moreover, the thermoelements 2a and 2b composing the module are thermically connected in parallel in order to optimize the heat flux through the module from its first face 4a towards its second face 4b as well as its electric resistance, thanks to the application of a heat gradient (ΔT=T_{c}−T_{f}) from the face 4a towards the face 4b. Such a heat flux then involves a displacement of the charge carriers and thus the appearance of an electrical current I.

In particular, when the thermoelements 2a and 2b have respectively a positive Seebeck coefficient (noted S₂ₐ) and a negative Seebeck coefficient (S_{2b}), their Seebeck coefficients add to each other and the potential difference V for the module has the following formula:

V=N×(S_{2b}−S₂ₐ)×ΔT=N×Sₙₚ×ΔT

where:
N corresponds to the number of couples of thermoelements 2a and 2b in a module,
ΔT corresponds to the heat gradient (T_{c}−T_{f}) applied between the two faces 4a and 4b of the thermoelectric converter, also called heat and cold areas of the converter and
Sₙₚ corresponds to the differential Seebeck coefficient between the thermoelements 2a and 2b.

The maximum power output by such a thermoelectric converter, for a resistive charge equal to the internal resistance of the converter rᵢₙₜ, has the following formula (1):

$${P}_{max} = \frac{{S}_{np}^{2} \times {( {T}_{c} - {T}_{f} )}^{2}}{2 \times {r}_{int}} \qquad ( 1 )$$

where T_{c} and T_{f} are respectively the temperature of the hot area and the temperature of the cold area of the converter.

In addition, the ideal output of such a converter corresponds to the ratio of the useful electric power, output to a load resistor R equal to the internal resistance of the converter, to the heat flux through the material. It has in particular the formula (2) below:

$$η = \frac{{T}_{c} - {T}_{f}}{{T}_{c}} \frac{\sqrt{1 + {ZT}_{m}} - 1}{\sqrt{1 + {ZT}_{m}} + \frac{{T}_{f}}{{T}_{c}}} \qquad ( 2 )$$

with

$${T}_{m} = \frac{{T}_{c} + {T}_{f}}{2}$$

and ZTₘ corresponding to a coefficient called “factor of merit” directly depending on the electric and thermal properties of the thermoelectric materials used to constitute the thermoelements 2a and 2b.

The equations (1) and (2) then show that the power and the output of the thermoelectric converters are directly related to the heat gradient (ΔT=T_{c}−T_{f}) applied between the two faces of the thermoelectric converter. Thus, in any system of the thermoelectric converter type, the existence of a heat gradient is thus determining for its performance and in particular to obtain a good energy effectiveness.

The heat gradient applied to the thermoelectric converter depends in particular on the heat source used to maintain the face 4a of the thermoelectric converter at a temperature called hot temperature T_{c} and on the heat dissipater used to maintain the face 4b of the thermoelectric converter at a temperature called cold temperature T_{f}.

For the heat source, it has been proposed to exploit the heat produced by an exothermic chemical reaction as the catalytic combustion of hydrogen or another fuel such as butane, propane or ethylene. The generated heat then makes it possible to maintain the face 4a of the thermoelectric converter at a sufficiently high temperature T_{c}.

On the other hand, to obtain a sufficiently high heat gradient in order to guarantee a high energy performance, the system allowing to evacuate the thermal power accumulated by the thermal converter, on the cold side thereof, must be powerful in order to obtain a temperature T_{f} much lower than T_{c} (ΔT>200° C. at the thermal balance). However, the powerful solutions in terms of cooling currently used are bulky and consume a part or the totality of the energy produced by the thermoelectric converter. That explains the low densities of power and the poor overall energy yield of the existing systems: energy lost in the ventilators, in a system with a circulation of water or cooling fluid or in the production of a cooling fluid and of fuel.

As an example, the U.S. Pat. No. 6,313,393 proposes an electric power generator using a microstructured architecture in order to improve the transfer of heat. Such a generator contains a combustion chamber in the form of a microchannel, used as a heat source. The chamber is in particular the center of an exothermic chemical reaction of a fuel. The heat released by the chemical reaction is then transferred to a device intended to convert thermal energy into electrical current, which can be then transmitted outside the device by means of output wires. Then, after flowing through the device, the heat flux is recovered by a heat dissipator. This dissipator can be formed for example by a thermal desorbor, a system provided with microchannels for the passage of a cooling fluid in order to form a heat exchanger, a microchemical reactor, center of an endothermic chemical reaction.

### OBJECT OF THE INVENTION

The object of the invention is to propose an electric generator based on a thermoelectric effect whose energy performance is improved compared to the state of the art.

In particular, the object of the invention is to provide an electric generator based on a thermoelectric effect including a thermoelectric converter to which a high heat gradient can be applied without the overall energy performance of the electric generator not being degraded, while being sufficiently compact and easy to implement.

According to the invention, this objective is reached in that an electric generator based on a thermoelectric effect including at least:
a heat source, center of an exothermic chemical reaction and including means for supplying with at least one reagent said exothermic chemical reaction,
a heat dissipator, center of an endothermic chemical reaction and including means for evacuating at least one product of the endothermic chemical reaction,
and a thermoelectric converter provided with at least two areas respectively in contact with the heat source and the heat dissipator,
   is characterized in that the means for supplying the heat source are connected to the means for evacuating for the heat dissipator, said product of the chemical endothermic reaction forming said reagent of the exothermic chemical reaction.

According to the invention, this objective is also reached by a method of implementation of such an electric generator characterized in that said product of the chemical endothermic reaction forming said reagent of the exothermic chemical reaction is hydrogen.

This objective is also reached by a manufacturing method for such an electric generator based on a thermoelectric effect, characterized in that it is obtained by at least one step of powder injection molding, in particular of nanometric size.

### BRIEF DESCRIPTION OF THE DRAWINGS

Other advantages and characteristics will more clearly arise from the following description of specific embodiments of the invention given as nonrestrictive examples and represented in the annexed drawings, in which:

FIG. 1 represents a sectional view of a schematic diagram of a thermoelectric converter;

FIG. 2 represents a schematical sectional view of a first embodiment of an electric generator according to the invention;

FIG. 3 represents the evolution of respectively hot and cold temperatures according to the flowing of the reagents through the channels in the electric generator according to FIG. 2;

FIGS. 4 and 5 represent respectively a sectional view and a schematic view of specific embodiments of an electric generator including a fuel cell coupled with the thermoelectric converter;

FIG. 6 illustrates schematically and in a sectional view a second embodiment of an electric generator according to the invention;

FIG. 7 represents the evolution of respectively hot and cold temperatures according to the flowing of the reagents through the channels in the electric generator according to FIG. 4;

FIG. 8 illustrates a top view of an alternative embodiment of an electric generator according to FIG. 2;

FIG. 9 schematically represents a specific embodiment example of a generator according to the invention;

FIG. 10 represents the evolution of the power density according to the temperature T_{c} in the hot area for thermoelectric converters examples including thermoelements of different heights;

FIG. 11 represents the evolution of the output electric power and of the endothermic flow according to the mass flow rate of liquid reagents for the endothermic chemical reaction.

### DESCRIPTION OF SPECIFIC EMBODIMENTS

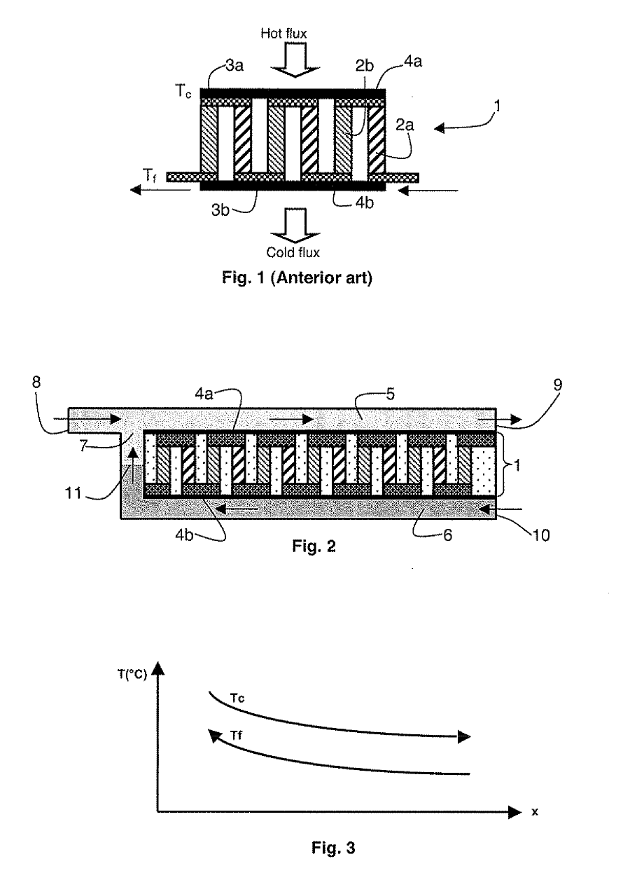

According to a specific embodiment illustrated in FIGS. 2 and 3, an electric generator based on a thermoelectric effect contains a thermoelectric converter 1, such as represented in FIG. 1.

Moreover, the thermoelectric converter 1 is interposed between a heat source and a heat dissipator in order to obtain a heat gradient ΔT=T_{c}−T_{f} between the two opposite faces 4a and 4b of the thermoelectric converter 1. The faces 4a and 4b form respectively the heat and cold areas of the thermoelectric converter 1, each of them being submitted to a heat flux, a hot one (φₕₒₜ) for the hot area and a cold one (φ_{cold}) for the cold area.

In FIG. 2, the heat source and the heat dissipator are respectively formed by first and second circulation channels 5 and 6, having parallel longitudinal axes. Moreover, the two opposite faces 4a and 4b of the thermoelectric converter 1 respectively delimit part of the first and second circulation channels 5 and 6. In addition, the first and second circulation channels 5 and 6 are each intended to be the center of a chemical reaction: an exothermic chemical reaction for the first circulation channel 5 and an endothermic chemical reaction for the second circulation channel 6.

The first circulation channel 5 comprises at one of its ends at least one input opening 7 intended to supply the first circulation channel 5 with at least one reagent of the exothermic chemical reaction. In FIG. 2, it also comprises in an advantageous way an additional input opening 8 arranged near the first input opening 7. This additional input opening 8 is more particularly intended to supply the first circulation channel 5 with another reagent of the exothermic chemical reaction. The first circulation channel 5 finally comprises at its other end an output opening 9 arranged at the other end of the first circulation channel 5.

The exothermic chemical reaction is advantageously a catalytic combustion reaction for hydrogen (H₂ or dihydrogene). According to this chemical reaction, hydrogen reacts with oxygen, for example provided by the ambient air, in order to produce water and heat. The combustion reaction for hydrogen is very energetic with a calorific value of 140 MJ/kg. Moreover, the flame temperature of this combustion reaction can reach more than 1500° C. In certain cases, hydrogen can be replaced by another fuel, such as butane. However, hydrogen remains the preferred fuel because it has a calorific value higher than that of another fuel. Butane has a calorific value of 50 MJ/kg.

In general, such a reaction is carried out with the help of a catalyst, which makes it possible to improve its output. The catalyst advantageously used is platinum, for example in a nanometric form such as platinized carbon, but it can also be selected among ruthenium, thorium, silver, copper, zinc, an alloy of iron and palladium, nickel and manganese. As an example, the first circulation channel 5 can be formed for example by a wall whose internal surface is covered with platinum particles, of micrometric or nanometric size. Moreover, the catalytic coating formed by these platinum particles can in an advantageous way have a strong porosity, in order to increase the surface reaction, and thus the reaction yield.

Thus, the exothermic chemical reaction occurs inside the first circulation channel 5, which then forms a catalytic combustion chamber, while making a rectional mixture circulate inside it from the input openings 7 and 8 to the output opening 9. Initially, the rectional mixture is mainly composed of air and of hydrogen, then it becomes gradually richer with water steam along the circulation channel 5 in favor of the initial reagents, until it mainly includes water at the output opening 9, indeed only water according to the length of the first channel 5. The water produced by the exothermic chemical reaction can advantageously be collected at the output opening 9. In particular, according to the type of endothermic reaction, it can be used as a reagent for the endothermic chemical reaction. Thus, the heat released along the first circulation channel 5 is decreasing from the input openings 7 and 8 to the output opening 9. This is more particularly illustrated in FIG. 3 which represents the evolution of the temperature T_{c} corresponding to the hot temperature obtained on the face 4a of the thermoelectric converter.

In addition, the second circulation channel 6 comprise at one of its ends at least one first input opening 10 intended to supply the second circulation channel 6 with at least one reagent of the endothermic chemical reaction. It also comprises, at its other end, an output opening 11, intended to evacuate the rectional mixture of the endothermic chemical reaction and more particularly at least one product of the endothermic chemical reaction. In addition, this output opening 11 is connected to the input opening 8 of the first circulation channel 5.

The endothermic chemical reaction is indeed selected so that at least one of its products forms one of the reagents of the exothermic chemical reaction. In particular, if the exothermic chemical reaction is a catalytic combustion reaction for hydrogen, the endothermic chemical reaction is selected among the reactions making it possible to obtain hydrogen so that, once formed, it is redirected towards the input opening 7 of the first circulation channel 5.

There are several endothermic chemical reactions making it possible to produce hydrogen: reforming of ethanol, methanol, ethylene glycol, methylcyclohexane, glycerol, hexane, methane, or ammonia cracking.

Tables 1 and 2 below show, as an example, the energy balance of the endothermic chemical reactions for a reforming process from two compounds: methanol and methylcyclohexane.

TABLE 1
Endothermic reaction: CH₃—OH + H₂O -> 3H₂ + CO₂ at 200° C.

| | |
|---|---|
| Δ_{Hr(g)} (J/mol) | 49000 |
| Δₑᵥₐₚ CH₃—OH | 37000 |
| Δₑᵥₐₚ H₂O | 44000 |
| ΔH_{endothermic} (J/mol) | 130000 |
| Q_{endothermic} (J/kg) | 2600000 |
| Q_{endothermic} (Wh/kg reagents) | 722 |

TABLE 2
Endothermic reaction: C₇H₁₄ -> 3H₂ + C₇H₈ at 350° C.

| | |
|---|---|
| Δ_{Hr(G)} (J/mol) | 215000 |
| Δₑᵥₐₚ C₇H₁₄ | 35800 |
| ΔH_{endothermic} (J/mol) | 250800 |
| Q_{endothermic} (J/kg) | 2559184 |
| Q_{endothermic} (Wh/kg reagents) | 711 |

In a preferential way, the endothermic chemical reaction is a steam reforming reaction from methanol, consisting in making methanol react in the presence of heat and water steam to produce hydrogen and carbon dioxide. Indeed, among various hydrocarbons, the choice of methanol has many advantages: it is easy to produce, it is not very toxic in particular in comparison with ammonia and other hydrocarbons. It reforms at moderate temperatures (typically 150-250° C.) compared to other hydrocarbons (mainly from 300° C. to 600° C.) and it has a high endothermic energy density during the chemical reaction (evaporation+reforming). It absorbs a lot of energy (≈720 kJ/kg), which makes it possible to balance the heat fluxes between the heat and cold areas in the thermoelectric converter 1.

In addition, the yield of the steam reforming reaction for methanol can be close to 100%, for temperatures between 250° C. and 300° C., when the reaction is carried out in the presence of a catalyst chosen among copper, zinc, aluminum, zirconium and palladium. Thus, the second circulation channel 6 can be formed, like the first circulation channel 5, by a wall whose internal surface is covered with catalyst particles, of micrometric or nanometric size.

In the generator 1 according to FIG. 2, the endothermic chemical reaction occurs inside the second circulation channel 6 by making a rectional mixture circulate inside it, from the input opening 10 to the output opening 11. The second circulation channel 6 thus forms a reforming chamber in the case of an endothermic chemical reaction, for example by reforming of methanol. At the input opening 10, the rectional mixture is mainly composed of methanol and water steam and it gradually becomes richer with hydrogen and carbon dioxide along the second circulation channel 6 in favor of the initial reagents until it mainly contains at the output opening 9 the products of the reaction (according to the length of the second circulation channel). Thus, the absorbed quantity of heat along the second circulation channel 6 is decreasing from the input opening 10 to the output opening 11, which induces an increase in the temperature along the second circulation channel 6. This is more particularly illustrated in FIG. 3 which represents the evolution of the temperature T_{f} corresponding to the so-called cold temperature obtained on the face 4b of the thermoelectric converter.

In the case of a reforming reaction for methanol or other hydrocarbons, the reagents of the endothermic chemical reaction that have not reacted at the output opening 11 can be directed, like hydrogen, towards the input opening 7 of the first circulation channel 5, in order to be consumed there by catalytic combustion and to contribute to the heat flux.

In FIG. 2, the rectional mixtures circulate respectively through the first and second circulation channels 5 and 6, in opposite directions, which allows, as illustrated in FIG. 3, to optimize the heat gradient (T_{c}−T_{f}) along the way of the two rectional mixtures. The heat gradient will be then transformed into electrical current by Seebeck effect thanks to the thermoelectric converter 1. Moreover, the heat gradient obtained is advantageously higher than 200° C.

Thermically coupling a thermoelectric converter with a heat source forming the center of an exothermic chemical reaction in order to generate the hot flow and with a heat dissipator forming the center of an endothermic chemical reaction in order to generate not only the cold flow but also the reagent of the exothermic chemical reaction makes it possible to obtain an electric generator whose performance, in particular energy performance, can be improved.

This is partly carried out by choosing a specific endothermic chemical reaction, so that at least one of the products of said reaction is also one of the reagents of the exothermic chemical reaction, the latter being then at least partly redirected from the heat dissipator to the heat source.

With such a solution, it is thus possible to obtain a high heat gradient at the thermal balance, while being freed from the problems of spatial requirement for storing the reagent of the exothermic chemical reaction or due to the big size of the heat dissipators according to the anterior art and from the problems of energy supply to make the heat dissipator work.

In addition, the fabrication of such an electric generator as well as its starting are simplified. Moreover, it is obtained a considerable reduction of the mass of the reagents at work, which makes it possible to increase the mass energy density of the electric generator based on a thermoelectric effect. Moreover, the electric generator based on a thermoelectric effect is energetically autonomous, has small spatial requirement and is energitically optimized.

However, obtaining such a performance and in particular energy performance with such an electric generator remain delicate because many factors related to the operation of this generator must be taken into account to find the single and optimal operating point for the electric generator. In particular, it is necessary to obtain:
a good chemical coupling between the two chemical, respectively endothermic and exothermic, reactions,
a good thermal coupling allowing to ensure heat exchanges from the heat source to the heat dissipator and
a good electric coupling allowing to ensure the production of the required electric power.

These three types of coupling are, in addition, dependant on each other.

The catalytic combustion reaction of hydrogen is, for example, five times more energetic than the reforming reaction from methanol. Thus, if the reforming reaction for methanol is complete, only one fifth of the produced hydrogen is used for the exothermic catalytic-combustion reaction.

Consequently, to obtain a balance, it can be useful to moderate the chemical catalytic-combustion reaction by controlling the air flow through the additional input opening 8. An oxygen deficit or excess indeed makes it possible to lower in a significant way the yield of the catalytic combustion reaction.

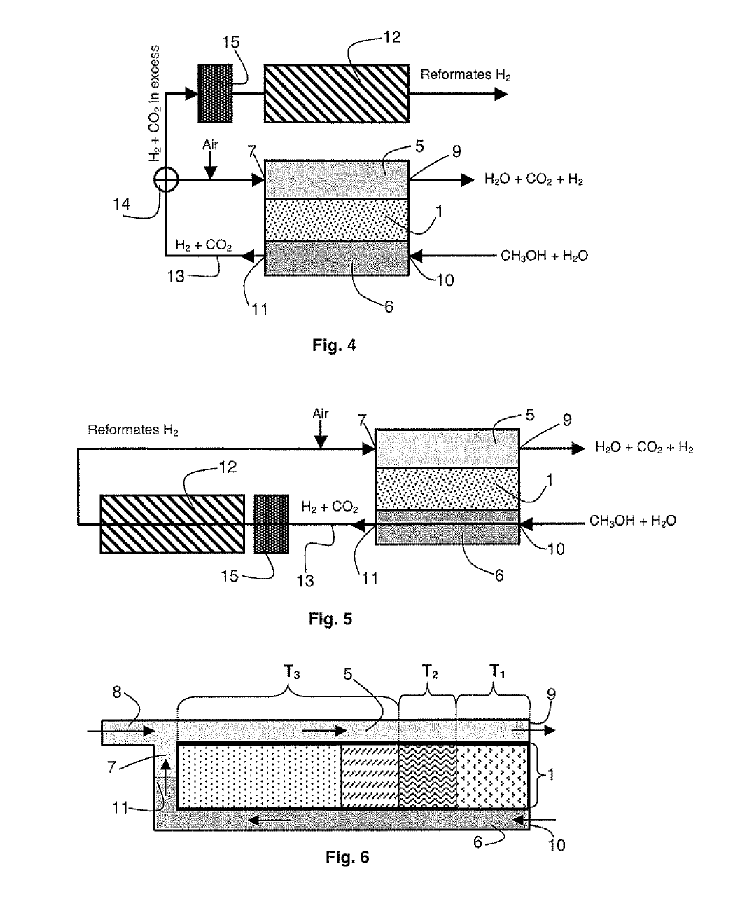

According to another alternative, it is also possible to associate the thermoelectric converter with a fuel cell in order to consume the hydrogen produced in excess by the endothermic chemical reaction, after a possible filtering. As an illustration, FIGS. 4 and 5 represent embodiments of an electric generator including a fuel cell connected to the means of evacuation in the second circulation channel in order to collect the hydrogen produced in excess.

In particular, in FIG. 4, a thermoelectric converter 1 is arranged between a combustion chamber 5 and a reforming chamber 6. The reforming chamber 6 includes an input 10 making it possible to supply the reforming chamber with methanol and water and an output 11 making it possible to evacuate at least the products of the reforming process, i.e. mainly hydrogen and carbon dioxide. The output 11 is connected via a supplying tube 13 to a valve 14 which directs said products either towards the input of the combustion chamber 7, or towards the input of the fuel cell 12. In addition, a filtration system for carbon dioxide 15 is arranged between the input of the fuel cell 12 and the valve 14. In this embodiment, the fuel cell thus uses the hydrogen that is produced in excess by the reforming chamber and that is not useful for the combustion chamber.

Conversely, in another embodiment represented in FIG. 5, it is possible to supply the combustion chamber 5 with the hydrogen that has not been used by the fuel cell 12. Thus, in this case, the fuel cell 12 is arranged between the input 7 of the combustion chamber 5 and the output 11 of the reforming chamber 6 in order to collect the hydrogen that has not been consumed by the fuel cell 12 and that initially comes from the reforming chamber 6.

According to another development of the invention, the electric generator can include other elements than the fuel cell. For example, it can include a series of microturbines arranged before the input of the heat dissipator, in order to collect the mechanical energy produced by the circulation of the reagents of the endothermic chemical reaction. The addition of this series of microturbines can make it possible to increase the energetic efficiency of the electric generator.

In addition, concerning the endothermic chemical reaction, it is preferable to use a low reforming temperature in order to guarantee the highest possible heat gradient between the hot and cold areas in the thermoelectric converter. This can be obtained, for example, by controlling the ratio “steam to carbon”, also written SIC. In the case of methanol, it could be possible to carry out the reaction of steam reforming at 50° C. with a ratio SIC from 4 to 5. However, at 50° C., the steam reforming reaction also produces carbon monoxide. However, this product can be harmful, in particular when the generator includes a fuel cell. Thus, the steam reforming reaction for methanol is advantageously carried out at reforming temperatures between 200° C. and 400° C. and advantageously between 250° C. and 300° C.

It also appears that the main parameter making it possible to obtain a good operating point is the thermal conductivity of the thermoelectric converter. However, to be able to control this parameter in order to ensure the correct operation of the device and thus to find the best compromise to generate a sufficient electric power, it is necessary to be ensured that:

1) the temperature T_{c} in the combustion chamber is maximum (750-800° C. for a catalytic combustion reaction for hydrogen coupled with a steam reforming reaction for methanol), in order to obtain a very high heat gradient and thus a maximum electric power output,
2) the temperature T_{f} in the heat dissipator is minimal in order to ensure the correct operation thereof and to maximize the reaction yield. For example, T_{f} is about 200° C. to 400° C. in the case of the steam reforming from methanol coupled with a catalytic combustion reaction of hydrogen,
3) the heat source and the heat dissipator have dimensions (size of the channels, catalyst, . . . ) allowing for each element to obtain the highest possible reaction yield and
4) the thermoelectric converter is thermically dimensioned.

Contrary to the heat source and to the heat dissipator, the thermoelectric converter cannot be dimensioned only by taking account of its own performance. It is not possible indeed to attempt to obtain a maximum electric power output, with a maximum filling ratio and a low height for the thermoelements in order to decrease the internal resistance of the converter. Indeed, the thermoelectric converter depends on the heat source and the heat dissipator, because it is in physical contact with these two elements. It is thus necessary to dimension its thermal conductivity so that, for a T_{c} value fixed at a preset temperature (for example between 700° C. and 800° C.) and for a quantity of absorbed energy predetermined by the endothermic reaction, the value T_{f} is maintained at a predetermined temperature (for example between 200° C. and 400° C. in the case of a steam reforming from methanol coupled with a catalytic combustion reaction for hydrogen).

In short, the thermoelectric converter must be designed, from a dimensional point of view, in order to obtain a compromise between the optimal thermal conductivity, which makes it possible to ensure the correct operation of the device, and the electric power output by the device. More particularly, it is thermically dimensioned to comply with the following formulas:

φ_{conduction}=φ_{cold}−φ_{SeebeckCold}−φⱼₒᵤₗₑ

φ_{conduction}=φₕₒₜ−φ_{SeebeckHot}+φⱼₒᵤₗₑ

in which:

φ_{conduction} is the heat flux through the thermoelectric converter from the first area to the second area,

φ_{cold} and φₕₒₜ are the heat fluxes respectively absorbed by the endothermic chemical reaction and the exothermic chemical reaction,

φ_{SeebeckHot} and φ_{SeebeckCold} are the Seebeck heat fluxes respectively in the area (4a) in contact with the heat source and in the area (4b) in contact with the heat dissipator and, more particularly, that is to say φ_{SeebeckHot}=N.S.I. T_{c} and φ_{SeebeckCold}=N.S.I. T_{f} with N corresponding to the number of thermoelements forming the thermoelectric generator, S corresponding to the Seebeck coefficient of the material, I being the current through the thermoelements and T_{f} and T_{c} are respectively the temperatures in the areas 4a and 4b, and

φⱼₒᵤₗₑ is the heat flux produced by Joule effect in the thermoelectric converter.

As an example, for a flow of 250 g/h of methanol and water (that is φ_{endo}=90 W/cm²), for a filling ratio (surface of the converter/cumulated surface of the thermoelements) of 50%, and a value of Tc regulated at 700° C. (via the exothermic reaction yield), it is necessary that the thickness of the thermoelements be between 0.8 mm and 1.5 mm, so that T_{f} lies between 200° C. and 400° C.

The nature of the material(s) forming the thermoelements 2a and 2b of the thermoelectric converter 1 are advantageously selected according to the range of temperature considered, both for the hot area and the cold area. Thus, the thermoelements 2a and 2b can be made of SiGe if the endothermic chemical reaction is a catalytic steam reforming reaction of methanol and the exothermic chemical reaction is a catalytic combustion reaction of hydrogen. Indeed, SiGe has the best thermoelectric performance in the range of temperature considered for this couple of chemical reactions, i.e. a maximum temperature in the hot area (T_{c}=900° C.) and a minimal temperature in the cold area (T_{f} of about 150° C.), with an average temperature of about 525° C. between the heat and cold areas.

As example, in the case of a SiGe-based thermoelectric converter and by using the reforming of methanol to absorb the combustion energy on the cold side and to produce hydrogen, the theoretical maximum electric energy density E_{elec}^{max} is equal to 38 Wh/kg (methanol+water), with T_{c}=800° C. and T_{f}=300° C. Moreover, by using a nanostructured-SiGe-based thermoelectric converter, it is possible to obtain an energy density of about 60 Wh/kg.

Other thermoelectric materials can also be used, as the alloy Bi₂Te₃. In particular, this alloy can be used in combination with the alloy SiGe in order to form segments in the module, the segment formed by couples of thermoelements 2a and 2b made of Bi₂Te₃ is advantageously arranged in the area where the temperature Tc is lower.

Advantageously, if the main reagent of the endothermic chemical reaction is in a liquid form, as it is the case for ammonia, methanol or ethanol mixed with water, the endothermic vaporization energy for said reagents, before the endothermic chemical steam reforming reaction itself, can be collected in order to obtain a better cooling on the cold side of the thermoelectric converter 1. Moreover, the thermoelectric converter 1 can advantageously include, at the input of the second circulation channel 7 and the output of the first circulation channel 6, an area formed by a purely thermically conducting material, without any thermoelement, in order to optimize the energy balances.

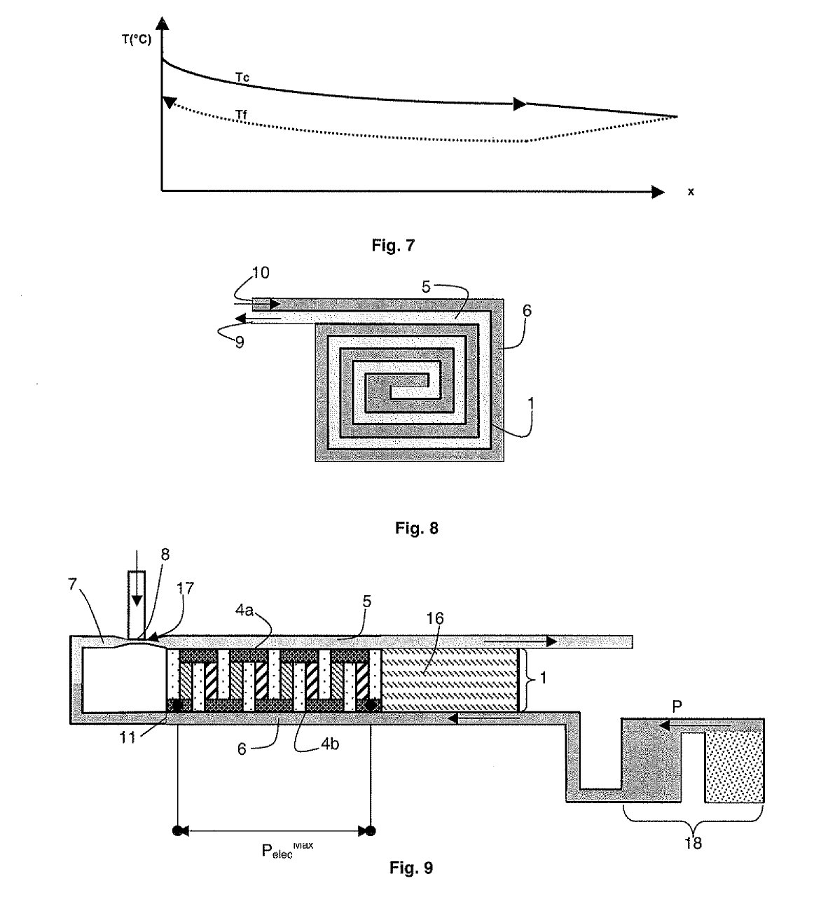

As an example and as illustrated in FIGS. 6 and 7, instead of only one type of couples of thermoelements, the thermoelectric converter 1 can include at least two distinct couples of thermoelements, in order to define various areas of heat exchange between the first and second circulation channels 5 and 6. In particular, in FIG. 6, the thermoelectric converter 1 includes 3 areas, T₁, T₂ and T₃, whose optimal performance (maximum factor of merit) correspond to the steady-state range of temperatures (FIG. 7). As an example, the thermoelectric converter 1 includes an area T₁ arranged at the input of the second circulation channel 6 and the output 9 of the first circulation channel 5. This area T₁ is advantageously an area allowing the evaporation of the liquid reagents for the endothermic chemical reaction. In this case, this area does not include any thermoelements, but is formed by a thermically conducting material. It is arranged beside an area T₂, intended for pre-heating said reagents, once those have vaporized, and also made of a thermically conducting material. In an alternative embodiment, the areas T₁ and T₂ can be merged. An area T₃ which can include at least two types of thermoelements, for example made of Bi₂Te₃ for the low temperatures, in the vicinity of the area T₂ and made of SiGe for the high temperatures when the rectional mixture moves towards the output opening 11 of the second circulation channel.

Moreover, the thermoelements 2a and 2b can be formed by nanostructured thermoelectric materials, favoring the diffusion of the phonons at the interfaces between the nanoaggregates, which makes it possible to reduce considerably their thermal conductivity and at the same time to improve their thermoelectric performance.

The first and second circulation channels are not necessarily rectilinear like those represented in FIGS. 2 and 6. They can have another form. As an example and as illustrated in FIG. 8, they can have a spiral configuration. Such a form is advantageous, because it makes it possible to limit thermal leaks. As the hottest point of the generator is in the center of the spiral, it is thus isolated from outside. Another possible form is the toroidal configuration. In the same way, the heat source and the heat dissipator can be formed by a set of channels or microchannels arranged according to a socalled “constructal” geometry, whose surface is covered by the catalyst and is intended to improve heat exchanges. Geometries of the tree-structured type can also be used.

The second circulation channel 5 forming the heat dissipator can advantageously be replaced by any other means making it possible to carry out the endothermic chemical reaction, insofar as it makes it possible to redirect at least one of the products of the endothermic chemical reaction towards the heat source, so that the product of the endothermic chemical reaction can be used as a reagent for the exothermic chemical reaction. As an example, the second circulation channel 6 can be replaced by a porous thin film, for example made of alumina or nickel, including a plurality of pores, advantageously of micrometric size and covered by a catalytic coating for the endothermic chemical reaction. In this case, the deposition of the catalyst can be carried out by a technique of impression, such as the technique of ink jet impression, or by techniques of chemical vapor deposition. It is the same thing for the first circulation channel 5.

The introduction of the reagents of the endothermic chemical reaction can also be carried out by any suitable means. For example, it is possible to use a pump for injecting the reagents when those are liquid. Another solution can also consist in using the heat released by the exothermic chemical reaction for pumping reagents when those are liquid. As an illustration, one can use the socalled capillary pumping technique consisting in evaporating the fluid to be pumped inside a capillary tube. At the interface fluid-gas, it is then formed a meniscus generating a pressure intended to aspire the fluid. In the case of reactive gases, if the gas is under pressure (for example in the case of butane), this pressure can be used to supply the heat dissipator with the reagent, for example by using an injector also carrying other fluids.

The introduction of the reagents of the exothermic chemical reaction can also be carried out by any known means, if at least one part of the product obtained by the endothermic chemical reaction can be redirected towards the heat source in order to be used as a reagent in said exothermic reaction. Thus, the use of a conventional minipump for injecting gas reagents can be contemplated. It is also possible to use a pump based a a venturi effect, in the hydrogen distribution channels or a compressor of the type “Knudsen”.

The electric generator based on a thermoelectric effect can be carried out for example by techniques of deposition of thin films used in the field of microelectricity and which have the advantage of offering a great density of thermoelements and thus of electric energy. It can also be obtained by more traditional techniques, such as for example at least one step of powder injection molding or PIM, more particularly from powders of nanometric size (technical also called microPIM), or by thermoelectric material sintering or brazing.

In particular, the socalled “PIM” or “microPiM” technique indeed makes it possible to carry out, advantageously in only one step, parts formed by various types of materials, such as metals, ceramic materials, . . . , with complex patterns, while being inexpensive in order to carry out a mass production. Moreover, the “PIM” or “microPIM” method makes it possible to mix various materials, in order to carry out a co-injection. In particular, it is possible to produce a matrix of slightly electrically conducting material, such as porous silicon oxide intended to form the mechanical support of the thermoelements, with thermoelectric materials in the form of powders in the same operation. The fluid circulation channels and the catalyst deposition can also be carried out by this same technique, Thus, it is possible to integrate in the same plate:
fluid distribution channels
thermoelements
a gas-gas exchanger
a fluid vaporizer
a capillary pump

The complete system can include several plates and the assembly (right or spiral geometry) can be done in a final sintering step.

According to a specific embodiment, an electric generator such as represented in FIG. 9 was fabricated with a thermoelectric converter 1 including thermoelements made of SiGe, arranged on a mechanical support made of silicon oxide and whose thermoelectric characteristics are optimal for an average temperature Tₘ of 600° C. between the heat and cold areas, with:

λ=1.5 W/mK,

ρ=2.5 mΩ·cm and

and S=400 μV/K

wherein λ is the thermal conductivity of the converter, ρ is the electric conductivity and S is the total Seebeck coefficient of the converter.

The generator contains a heat source 5, center of a catalytic combustion of hydrogen and generating temperatures T_{c} between 750° C. and 900° C. on the hot face of the thermoelectric converter. More particularly, it is composed of a thin film made of porous alumina with coated platinized carbon.

It also contains a heat dissipator 6, center of a methanol steam reforming reaction, with a temperature T_{f} between 200° C. and 300° C. and being able to absorb 722 Wh/kg of reagents on the cold face of the thermoelectric converter 1. More particularly, the heat dissipator is composed of a thin film of porous alumina coated with nanometric particles of ZnO and CuO.

The heat gradient likely to be obtained for this generator is about 500° C. to 600° C. at the terminal of the converter. Moreover, the thermoelectric converter 1 includes an evaporator 16 arranged at the reagent input of the heat dissipator 6. A venturi pump 17 is also arranged between the output of the heat dissipator 6 and the input of the heat source 5, in order to supply the heat source 5 with air and a tank 18 with reagents is arranged before the heat dissipator 6.

It should be noted that, for such an electric generator, the cold flux is limited by the evaporation limit for water. Indeed, beyond the water calefaction regime (about 100 W/cm²), the liquid reagent tank for reforming methanol is isolated from the heat source 6 by a gaseous water film. Thus, the maximum quantity of energy that can be absorbed by the liquid reagent tank 18 (water+méthanol) is about 150 W/cm². The maximum power density of such a generator is thus about 7.5 W/cm², which is higher than that of fuel cells.

The parameters of the electric generator according to FIG. 9 are indicated in the table below.

TABLE 3

| Parameters | Unities | Value |
|---|---|---|
| Temperature of the hot area Tc | K | 1073 |
| Temperature of the cold area Tf | K | 573 |
| Height of the thermoelements H | M | variable |
| Surface of the hot source Ahs | M² | 1.00^{E}−04 |
| Total surface of the thermoelectric converter | M² | 1.00^{E}−04 |
| Ate | | |
| Total surface of the thermoelements Anp | M² | 4.00^{E}−06 |
| Thermal conductivity of the matrix made of | W/m/K | 0.08 |
| SiO₂ kSiO₂ | | |
| Thermal conductivity of the thermoelements | W/m/K | 3 |
| Knp | | |
| Seebeck coefficient of a thermoelement of the | V/K | −4.00^{E}−04 |
| type n Sn | | |
| Seebeck coefficient of a thermoelement of the | V/K | 4.00^{E}−04 |
| type p Sp | | |
| A number of junctions N | | 25 |
| Resistivity of the thermoelements Rho | Ohm · m | 5.00^{E}−05 |
| Width of the thermoelement Ith | M | 1.00^{E}−03 |

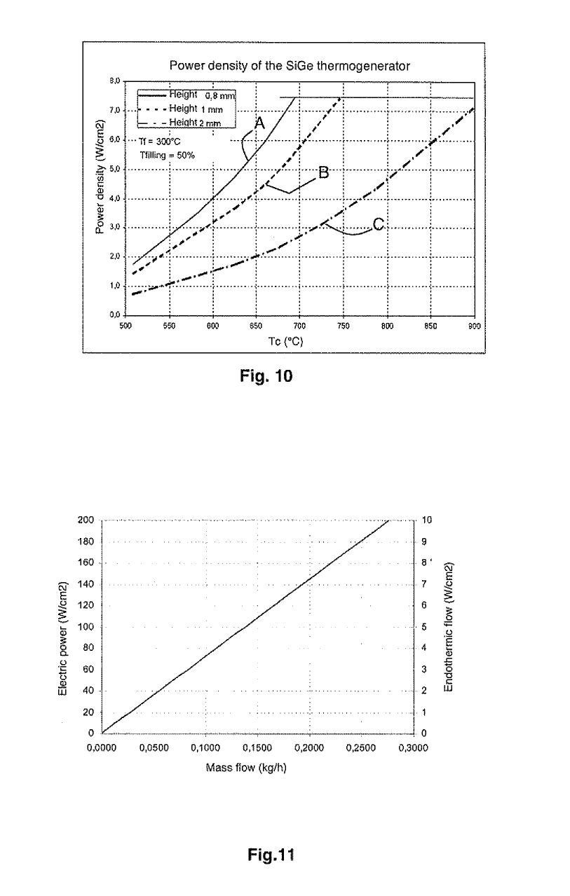

As illustrated in FIG. 10, the power density of generators such as that represented in FIG. 9 was measured according to the temperature T_{c}, for three heights of thermoelements: 0.8 mm (curve A), 1 mm (curve B) and 2 mm (curve C), in order to thermically dimension the converter according to the operating temperatures (both T_{c} and T_{f}), in order to maximize the power density and to avoid the calefaction regime. Thus, for the studied converter (with a thermoelement filling ratio of about 50%), the thermoelements must have a height of 1 mm to obtain a T_{c} of about 750° C. For other configurations of thermoelectric converters (with lower filling ratio, with other materials, and other geometrical arrangements), it would be necessary to re-examine thermal dimensioning of said converter, so that the conduction flux φ_{conduction} through the thermoelectric converter comply with the two formulas below:

φ_{conduction}=φ_{cold}−φ_{SeebeckCold}−φⱼₒᵤₗₑ

φ_{conduction}=φₕₒₜ−φ_{SeebeckHot}+φⱼₒᵤₗₑ

Moreover, in FIG. 11, the electric power output for the electric generator according to the example above as well as the endothermic flux has been evaluated according to the mass flow of the liquid reagents for the endothermic chemical reaction. The maximum power density (150 W/cm²) is obtained for a flow of 200 g/h of liquid reagents. This makes it possible to evaluate the mass density of electric energy of the generator:

E^{elec}ₘₐₓ=40 Wh/kg (methanol+water).

1-15. (canceled)

16. Electric generator based on a thermoelectric effect including at least:
a heat source, center of an exothermic chemical reaction and including inlet for supplying with at least one reagent said exothermic chemical reaction,
a heat dissipator, center of an endothermic chemical reaction and including outlet for evacuating at least one product of the endothermic chemical reaction,
and a thermoelectric converter provided with at least two areas respectively in contact with the heat source and the heat dissipator,
wherein the means for supplying the heat source are connected to the outlet for evacuating the heat dissipator, said product of the endothermic chemical reaction forming said reagent of the exothermic chemical reaction.

17. Generator according to claim 16, wherein the heat source and the heat dissipator are respectively formed by at least first and second circulation channels.

18. Generator according to claim 17, wherein the first and second circulation channels have parallel longitudinal axes and in that the thermoelectric converter is interposed between the first and second circulation channels.

19. Generator according to claim 18, wherein the first and second circulation channels have a spiral configuration.

20. Generator according to claim 16, wherein each of the first and second circulation channels is delimited by a wall including an internal surface provided with a catalytic coating for the endothermic or exothermic chemical reaction respectively associated with the first or second circulation channel.

21. Generator according to claim 16, wherein the heat dissipator includes a porous thin film including a plurality of pores covered with a catalytic coating for the endothermic chemical reaction.

22. Generator according to claim 16, wherein it includes a fuel cell connected to said outlet for evacuating the heat dissipator.

23. Generator according to claim 16, wherein the thermoelectric converter is thermically dimensioned to comply with the following formulas:
φ_{conduction}=φ_{cold}−φ_{SeebeckCold}−φⱼₒᵤₗₑ
φ_{conduction}=φₕₒₜ−φ_{SeebeckHot}+φⱼₒᵤₗₑ
in which:
fconduction is the heat flux through the thermoelectric converter from the first area to the second area,
fcold and fhot are the heat fluxes respectively absorbed by the endothermic chemical reaction and the exothermic chemical reaction,
fSeebeckHot and fSeebeckCold are the Seebeck heat fluxes respectively in the area in contact with the heat source and in the area in contact with the heat dissipator and
fjoule is the heat flux produced by Joule effect in the thermoelectric converter.

24. Generator according to claim 16, wherein the thermoelectric converter includes at least two distinct couples of thermoelements.

25. Method for implementing an electric generator based on a thermoelectric effect according to claim 16, wherein said product of the endothermic chemical reaction forming said reagent of the exothermic chemical reaction is hydrogen.

26. Method according to claim 25, wherein the exothermic chemical reaction is a catalytic combustion reaction of hydrogen and in that the endothermic chemical reaction is a catalytic reforming reaction.

27. Method according to claim 26, wherein the catalytic reforming reaction is carried out from methanol and water, with a catalyst selected among copper, zinc, aluminum, zirconium and palladium.

28. Method according to claim 27, wherein a heat gradient (DT) higher than 200° C. is maintained between the two areas of the thermoelectric converter.

29. Method according to claim 28, wherein as the heat source and the heat dissipator being respectively formed by first and second circulation channels with parallel longitudinal axes, first and second reactional mixtures circulate respectively through the first and second circulation channels, according to opposite directions.

30. Method for manufacturing an electric generator based on a thermoelectric effect according to claim 16, wherein it is obtained by at least one step of powder injection molding, in particular of nanometric size.
